(19) United States
(12) Patent Application Publication
(10) Pub. No.: US 2006/0202304 A1
(43) Pub. Date: Sep. 14, 2006

(54) Integrated circuit with temperature-controlled component

(76) Inventor: Raymond K. Orr, Kanata (CA)

Correspondence Address: SMART & BIGGAR;P.O. BOX 2999, STATION D, 900-55 METCALFE STREET, OTTAWA, ON, K1P5Y6, CA

(21) Appl. No.: 11/076,983

(22) Filed: Mar. 11, 2005

(51) Int. Cl. H01L 29/00

(52) U.S. Cl. 257/536; 257/537; 257/E27.047

(57) ABSTRACT

An integrated circuit has a circuit component and a heating component thermally coupled together in a region thermally isolated from other parts of the integrated circuit. The thermal isolation can be provided by a bridge over a cavity in the substrate or caps over a thin substrate. A control circuit, which may be responsive to a sensing component thermally coupled to the heating component, controls the heating component to heat the circuit component to a temperature greater than that of the other parts of the integrated circuit, to control a temperature-dependent characteristic of the circuit component. The circuit component can for example be a resistor whose resistance is precisely determined and/or adjusted via the control circuit.

This invention relates to integrated circuits, and is particularly concerned with an integrated circuit (IC) which includes at least one temperature-controlled component.

### BACKGROUND

It is well known that circuit components which are integrated into an IC can have one or more characteristics that are very dependent upon temperature, operating voltage, and manufacturing process variations.

By way of example, resistors created in silicon ICs can have large temperature coefficients of resistance ranging from 300 to 2500 ppm/° C. (parts per million per degree Celsius), which for an operating temperature swing of 100° C. can result in as much as a 25% change in resistance. The resistance can also typically vary by +20% with manufacturing process variations and may have a voltage dependence of the order of 2000 ppm/V. Resistors with tighter tolerances and/or small temperature dependence are desirable in a wide range of circuits.

More stable or precise resistances can be provided in ICs using closely matched resistances and active circuits such as voltage-controlled current sources. Where very stable resistors are required, discrete resistors external to the IC can be used. Such discrete resistors may be incorporated into a package of the IC or added separately on a circuit board. These techniques involve disadvantages such as extra costs, space requirements, and assembly processes, and the resulting resistance values may still be temperature-dependent.

It is known from Microbridge Technologies, Inc. to provide a polysilicon resistor whose resistance can be adjusted by an annealing process. This is facilitated by providing the adjustable resistor and a heating resistor on a bridge over a cavity etched into a silicon substrate to provide thermal isolation. In an adjustment process, the heating resistor is used to heat the adjustable resistor to a very high temperature, of the order of 800 to 1000° C., thereby to determine a precise (normal operating temperature) resistance of the adjustable resistor. This also enables the temperature coefficient of resistance (TCR) of the adjustable resistor to be adjusted within a limited range, but the TCR can not be reduced to zero. The adjustment process is separate from normal operation, so that dynamic adjustment of the resistance, i.e. adjustment of the resistance during normal use of the adjustable resistor, is not possible. In addition, this technique is limited to polysilicon devices such as resistors, and is not applicable to other circuit components, for example semiconductor devices, of an IC.

There is a need to provide an improved IC in which one or more circuit components, for example a resistor, can be controlled to have a precise characteristic, such as resistance, which is substantially independent of the operating temperature of the IC.

### SUMMARY OF THE INVENTION

One aspect of this invention provides an integrated circuit comprising a circuit component of the integrated circuit and a heating component thermally coupled together and relatively thermally isolated from other parts of the integrated circuit, and a control circuit for controlling the heating component for heating the circuit component to a temperature greater than a maximum operating temperature of said other parts of the integrated circuit.

The integrated circuit can include a sensing component thermally coupled to the heating component, the control circuit being responsive to the sensing component for controlling the heating component. The control circuit is preferably a part of the integrated circuit, and can be responsive to a control voltage for controlling the heating component. For example, at least one of the thermally coupled components can comprise a resistor.

In one form of the integrated circuit, the thermally coupled components are provided on a bridge over a cavity in the integrated circuit to provide the relative thermal isolation of the thermally coupled components from said other parts of the integrated circuit. In another form of the integrated circuit, the thermally coupled components are provided in a region of the integrated circuit having a relatively thin substrate and caps over said region to provide the relative thermal isolation of the thermally coupled components from said other parts of the integrated circuit.

Another aspect of the invention provides a method of controlling a temperature-dependent characteristic of a circuit component of an integrated circuit, comprising the steps of: thermally coupling the circuit component to a heating component and relatively thermally isolating the thermally coupled components from other parts of the integrated circuit; and controlling the heating component to heat the thermally coupled components to a temperature greater than a maximum operating temperature of said other parts of the integrated circuit.

The method may include the step of maintaining a substantially constant temperature of the thermally coupled components thereby to maintain said temperature-dependent characteristic of the circuit component substantially constant, or the step of controlling temperature of the thermally coupled components thereby to adjust said temperature-dependent characteristic of the circuit component. For example, the circuit component may comprise a resistor and the temperature-dependent characteristic may comprise a resistance of the resistor.

A further aspect of the invention provides an integrated circuit comprising: a substrate including a cavity in the substrate and a bridge over the cavity; a circuit component of the integrated circuit on the bridge whereby it is relatively thermally isolated from other parts of the integrated circuit not on the bridge; and a heating component on the bridge, the heating component and the circuit component being relatively thermally coupled together, whereby the circuit component can be heated by the heating component to a temperature greater than a temperature of said other parts of the integrated circuit.

Another aspect of the invention provides an integrated circuit comprising: a substrate having a region having caps providing relative thermal isolation of said region from other parts of the substrate; a circuit component of the integrated circuit in said region whereby it is relatively thermally isolated from other parts of the integrated circuit not in said region; and a heating component in said region, the heating component and the circuit component being relatively thermally coupled together, whereby the circuit component can be heated by the heating component to a temperature greater than a temperature of said other parts of the integrated circuit.

The invention also provides a method of making an integrated circuit having a substrate with a region having caps providing relative thermal isolation of said region from other parts of the substrate, comprising the steps of: providing a heating component and a circuit component of the integrated circuit in said region of a first wafer; etching an underside of a cap in a second wafer; contacting the first and second wafers to provide the cap over said region; backside grinding the first wafer to produce a relatively thin substrate in said region; etching an underside of a second cap in a third wafer; and contacting the first and third wafers to provide the second cap under said region.

### BRIEF DESCRIPTION OF THE DRAWINGS

The invention will be further understood from the following description by way of example with reference to the accompanying drawings, in which the same references are used in different figures to denote similar elements and in which:

FIG. 1 is a plan view illustrating parts of an IC in accordance with an embodiment of this invention;

FIG. 2 is a cross-sectional view of parts of the IC of FIG. 1, the cross-section being taken on the lines II-II of FIG. 1;

FIG. 3 is a plan view illustrating parts of an IC in accordance with another embodiment of this invention;

FIG. 4 is a cross-sectional view of parts of the IC of FIG. 3, the cross-section being taken on the lines IV-IV of FIG. 3;

FIG. 5 is a plan view illustrating parts of an IC in accordance with a further embodiment of this invention;

FIG. 6 is a plan view illustrating parts of an IC in accordance with another embodiment of this invention;

FIGS. 7 to 9 illustrate control circuits for the ICs of FIGS. 1 to 6 in accordance with embodiments of the invention; and

FIGS. 10 to 14 are sectional views illustrating steps in producing an IC in accordance with a further embodiment of the invention.

### DETAILED DESCRIPTION

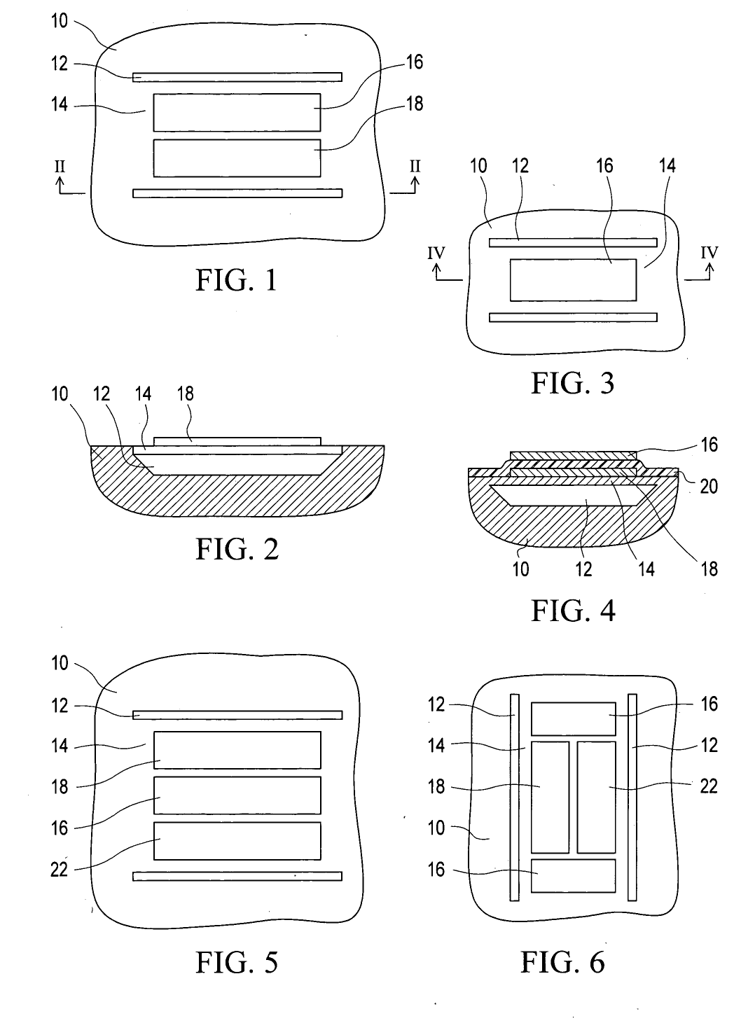

Referring to the drawings, FIG. 1 is a plan view, and FIG. 2 is a cross-sectional view, illustrating parts of an IC in accordance with an embodiment of this invention. In this example, the IC comprises a silicon substrate 10 of which only parts relevant to the invention are shown. The silicon substrate 10 is etched in known manner to form a cavity 12 with a bridge 14 of silicon remaining over the cavity 12. At least one heating component 16 and at least one circuit component 18 of the IC are provided on the bridge 14, and electrical connections (not shown) to these components 16 and 18 are provided in known manner, for example by conductors deposited onto the surface of the IC.

For example, the heating component 16 may be a resistor constituted by a layer of polysilicon or another resistive material formed on the bridge 14. The circuit component 18 may also be a resistor, constituted by another part of the layer of polysilicon or other resistive material formed on the bridge 14, whose resistance is to be determined or adjusted. The components 16 and 18 are arranged on the bridge 14 so that they are in close proximity to each other to be closely thermally coupled to one another, and so that they are relatively thermally isolated from the rest of the IC and its substrate 10 by the cavity 12.

In use of the IC, power is supplied to the heating component 16 thereby to heat the thermally coupled components 16 and 18 on the bridge 14. These components and the bridge can have a small size and a small thermal mass, so that very little heating power is required to heat the components to an elevated or controlled temperature. The thermal isolation of these components due to the cavity 12 prevents corresponding heating of other parts of the IC.

The thermally coupled components 16 and 18 on the bridge 14 can be heated to a temperature that is a little above a maximum operating temperature of other parts of the IC, so that this temperature can be maintained under all operating conditions of the IC. Such heating and its control are further described below. In this manner the bridge 14 and hence the circuit component 18 can be held at a desired temperature, so that a temperature-dependent characteristic of the circuit component 18 is held constant, and/or such a characteristic can be varied by adjusting the temperature of the bridge 14. For example, where the component 18 is a resistor as described above, the characteristic can be a resistance of the resistor.

Although FIGS. 1 and 2 illustrate particular shapes and configurations of the cavity 12, the bridge 14, and the components 16 and 18 on the bridge, it can be appreciated that these can all be arranged in any desired manner to suit the particular components, the thermal coupling among these components, and their thermal isolation from other parts of the IC.

By way of example, FIGS. 3 and 4 illustrate in plan and cross-sectional views, respectively, another embodiment of the invention in which the heating component 16 and the circuit component 18, both in the form of layers of polysilicon or other resistive material, are formed overlying one another with an insulating layer 20, for example of silicon oxide, between them. Electrical connections (not shown) are again made to the components 16 and 18 in known manner, and the operation in use of the IC of FIGS. 3 and 4 is similar to that described above.

FIG. 5 is a plan view illustrating parts of an IC in accordance with a further embodiment of the invention, which is similar to that of FIG. 1 but with the addition of another component 22 on the bridge 14. A cross-sectional view of the IC of FIG. 5 can be similar to that shown in FIG. 2. In this example the heating component 16 is provided between the components 18 and 22, so that these components are heated to substantially the same temperature by the heating component 16.

FIG. 6 is a plan view illustrating parts of an IC in accordance with another embodiment of the invention, in which the heating component 16 is divided into two similar parts which are provided at opposite ends of the bridge 14, and the circuit component 18 and the component 22 are provided on the bridge 14 between the two parts of the heating component 16. The two parts of the heating component 16 are supplied with the same power so that they are heated to substantially the same temperature; for example they can be equal resistances connected in series or parallel with one another. The components 18 and 22 on the bridge 14 between the heating component parts are at substantially identical temperatures with substantially no thermal gradient.

For example, the additional component 22 can be another resistor constituted by polysilicon or other resistive material as described above. This component 22 can have a size that is geometrically scaled to that of the circuit component 18, so that the component 22 can be used as a sensing component in the control circuit for the heating component 16 to maintain the desired characteristic of the circuit component 18, as described further below. For example, where the components 18 and 22 are resistors, the geometric scaling provides a predetermined ratio of the resistances of these components, and the resistance of the sensing component 22 can be used in the heating control circuit to maintain precisely a desired resistance of the circuit component 18.

It can be appreciated that, in the absence of a sensing component 22, a temperature-dependent characteristic (e.g. resistance) of the heating component 16 can be used for controlling the power supplied to the heating component 18, thereby to determine a temperature and hence characteristic (e.g. resistance) of the circuit component 18, for example as further described below with reference to FIG. 9. Such control may alternatively be open-loop or responsive to operation of other parts of the IC.

It can be appreciated that relative resistances (or other characteristics) of the components 16, 18, and 22 can be determined by their relative dimensions and/or layer thicknesses or materials, and that combinations and variations of the lateral arrangements of the components in FIGS. 1, 2, 5, and 6 and the overlying arrangement of the components in FIGS. 3 and 4 can also be provided.

Although the ICs as described above with reference to FIGS. 1 to 5 each include only a single heating component 16 and a single circuit component 18, it can be appreciated that a plurality of similar or different circuit components of the IC can be provided on a single bridge 14 and/or on a plurality of such bridges at different parts of the IC, and that each such bridge may include one or more heating components 16 and may include one or more sensing components 22. For example, FIG. 6 shows the heating component 16 being in two parts at the ends of the bridge 14. It will be appreciated that it may instead comprise an arbitrary number of parts arranged around the periphery of the bridge 14 or other area providing thermal isolation for the components 16, 18, and 22 from other parts of the IC.

Further, although only resistive components are specifically referred to above for constituting the components 16, 18, and 22, it can be appreciated that these components can comprise other IC components such as semiconductors and/or IC sub-circuits such as amplifiers, etc. By way of example, instead of being resistors the heating component 16 may be a semiconductor device, the circuit component 18 may be a transistor whose characteristic to be determined or adjusted may be a gain or another temperature-dependent parameter of the transistor, and/or the sensing component 22 may be a P-N junction of a diode or a diode-connected transistor.

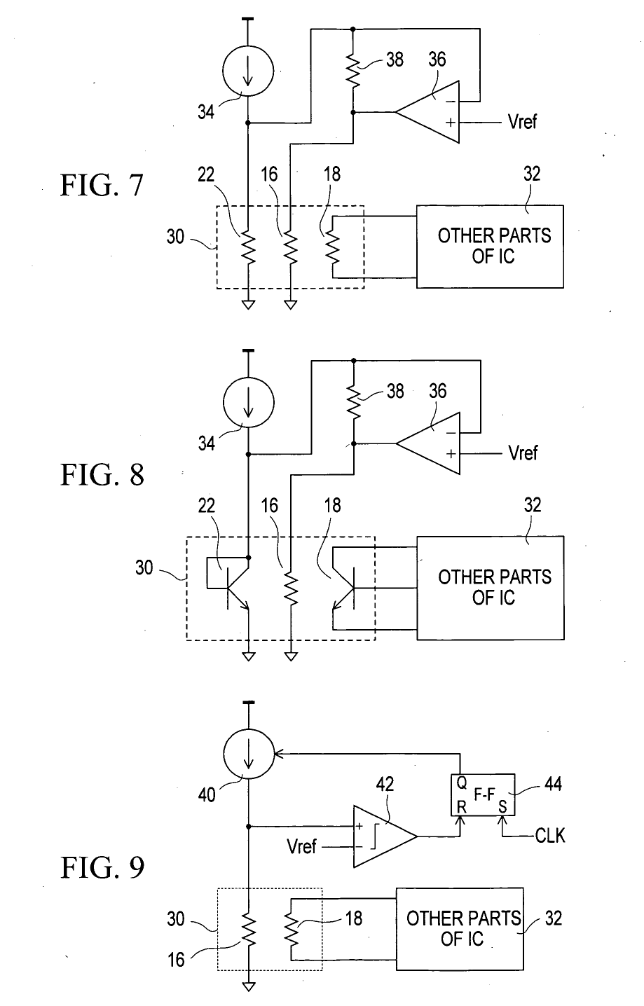

FIG. 7 illustrates one form of a control circuit for the IC of FIG. 5 or 6, assuming that the heating component 16, circuit component 18, and sensing component 22 are resistors. These components are illustrated in the circuit of FIG. 6 within a dashed-line box 30 representing the thermal coupling of these components and their thermal isolation from other parts of the IC, represented by a box 30.

The control circuit of FIG. 7 comprises a current source 34, a differential amplifier 36 having a non-inverting (+) input supplied with a control or reference voltage Vref, and a resistor 38 connected between an output and an inverting (−) input of the differential amplifier 36. The current source 34 is connected in series with the sensing resistor 22 between a positive supply voltage and ground, the non-grounded side of the sensing resistor 22 also being connected to the inverting input of the differential amplifier 36. The heating resistor 16 is connected between the output of the differential amplifier 36 and ground. It will be appreciated that the circuit resistor 18 does not require any electrical connection to the control circuit and can be electrically isolated therefrom, as shown in FIG. 6.

In operation, a constant current is supplied from the source 34 to the sensing resistor 22 to produce at the inverting input of the differential amplifier 36 a voltage that is proportional to the temperature-dependent resistance of the sensing resistor 22. The differential amplifier 36 amplifies a difference between this voltage and the reference voltage Vref with a gain determined by a ratio of the resistances of the resistors 38 and 22, and supplies a resulting voltage from its output to the heating resistor 16. Consequently, the heating resistor 16 is supplied with power to maintain a desired temperature of the thermally coupled resistors 16, 18, and 22, and hence a resistance of the sensing resistor 22. As the circuit resistor 18 is geometrically scaled to the sensing resistor and is at the same temperature, the control arrangement also maintains precisely a desired resistance of the circuit resistor 18.

The desired resistance of the circuit resistor 18 can for example be a constant value, which the control circuit maintains by maintaining a constant temperature of the thermally coupled resistors 16, 18, and 22. The circuit parameters are desirably chosen so that this constant temperature is greater than a maximum operating temperature of the other parts of the IC, so that there is always some heating by the heating resistor 16. Consequently, the ambient temperature and the operating temperature of the IC can vary within a wide range, while the control circuit maintains a higher constant temperature, and hence a constant resistance, of the circuit resistor 18. This provides the resistor 18 with a resistance that is precisely determined by the control circuit, and with the equivalent of a zero temperature coefficient of resistance (TCR) as far as ambient and IC operating temperatures are concerned.

It can also be seen that the temperature of the thermally coupled resistors 16, 18, and 22, and hence the actual resistance of the circuit resistor 18, are determined by the reference voltage Vref (as well as by other circuit parameters). Instead of maintaining a constant temperature and hence resistance by maintaining a constant value of the reference voltage Vref, this voltage Vref can be varied or controlled to determine and adjust the resistance of the circuit resistor 18. Such adjustment can be carried out dynamically in use of the IC in any desired manner, for example by supplying the reference voltage Vref in dependence upon operations in other parts of the IC.

Equivalently, another parameter of the control circuit, for example the current supplied by the current source 34, can be varied to adjust the resistance of the circuit resistor 18.

The circuit of FIG. 7 and the above description assume that the thermally coupled resistors 18 and 22 have a positive TCR. In this case, the resistors 18 and 22 are designed so that, at a temperature slightly above the maximum operating temperature of the IC, a maximum resistance (allowing for manufacturing process variations) of the resistor 22 is equal to or less than the desired resistance of this resistor 22. Process variations resulting in lower resistance values are then compensated by heating of the thermally coupled resistors.

Conversely, if the resistors 18 and 22 have a negative TCR, then the input polarity of the differential amplifier 36 is reversed from that shown in FIG. 7, and the resistors 18 and 22 are designed so that, at a temperature slightly above the maximum operating temperature of the IC, a minimum resistance of the resistor 22 is equal to or greater than the desired resistance of this resistor 22. In this case process variations resulting in higher resistance values are compensated by heating of the thermally coupled resistors.

FIG. 8 illustrates a modification of the control circuit of FIG. 7, in which the heating component 16 is a resistor and the sensing component 22 is a P-N junction constituted by a diode-connected bipolar transistor. The control circuit of FIG. 8 and its-operation are otherwise substantially the same as those of FIG. 7 as described above. The P-N junction constituting the sensing component 22, passing the current from the source 34, drops a voltage which is determined by the temperature of the junction, this voltage constituting a sensed input voltage to the differential amplifier 36 for control of the heating resistor 16 in a similar manner to that described above.

FIG. 8 also illustrates the circuit component 18 as being a bipolar transistor, connected to other parts of the IC, instead of a resistor. It can be appreciated that, because the circuit component 18 is electrically isolated from the control circuit including the heating and sensing components 16 and 22, the circuit component 18 can have any desired form and is not restricted to the particular forms described here.

Similarly, although the heating component 16 is conveniently a resistive layer constituting a resistor, it can instead take any other desired form to provide for heating of the thermally coupled components.

Temperature-dependent devices other than a resistor as shown in FIG. 7 and a P-N junction as shown in FIG. 8 can alternatively be used as the sensing component 22. In addition, as observed above the heating component 16 may alternatively be used also as a sensing element, for example by sensing its current and/or applied voltage.

FIG. 9 illustrates one form of control circuit which can be used in this respect, again assuming that the heating component 16 is a resistor. The heating component 16 and the circuit component 18, also illustrated as a resistor, are illustrated in the circuit of FIG. 9 within the box 30 representing the thermal coupling of these components and their thermal isolation from other parts of the IC, again represented by a box 32.

The control circuit of FIG. 9 comprises a current source 40, a comparator 42, and an RS flip-flop 44 having an output Q which controls the current source 40, turning it on in a set state and off in a reset state of the flip-flop. The current source 40, when it is turned on, supplies a constant current to the heating resistor 16, thereby producing a voltage drop across the heating resistor. The comparator 42 compares this voltage drop with a reference voltage Vref and, when the voltage Vref is exceeded due to heating of the heating resistor causing its resistance to increase (for a positive temperature coefficient), produces an output which is supplied to a reset input R of the flip-flop 44, thereby resetting the flip-flop and turning off the current source 40. The flip-flop 44 is set, thereby turning on the current source, by pulses of a signal CLK supplied to its set input S; these clock pulses are conveniently at a fixed rate with a period much less than a thermal time constant of the thermally coupled components.

Thus using the control circuit of FIG. 9 the temperature and resistance of the heating resistor 16 (and hence of the circuit component 18) are increased when the current source 40 is turned on, and decrease due to thermal losses from the bridge 14 to the rest of the IC when the current source 40 is turned off. The temperature thus varies within a small range dependent upon sensitivity of the comparator 42, but can be substantially constant and/or can be adjusted dependent upon parameters of the control circuit such as the voltage Vref, the pulse rate of the signal CLK, and the current of the current source 40.

Other forms of control circuit, for example using dual comparators to detect upper and lower temperatures, and switching between two different currents supplied by the current source 40 instead of turning it on and off, can alternatively be provided.

It will be appreciated that the control circuit can be conveniently incorporated into the IC, but this need not necessarily be the case and the control circuit can instead be provided separately from the IC using external connections to provide functions such as the sensing and control as described above.

Although a particular thermal arrangement is described above as comprising the silicon bridge 14, on which the thermally coupled components are provided, over the cavity 12 providing relative thermal isolation of these components from the other parts of the IC, it can be appreciated that other arrangements can be provided in order to achieve a desired thermal isolation. This may especially be the case where a maximum temperature to which the thermally coupled components are heated is not very much greater than a maximum operating temperature of the other parts of the IC (in contrast to the high annealing temperatures used in the prior art adjustment process described above), so that requirements for relative thermal isolation of the thermally coupled components may be less stringent. In such a case, for example, a sufficient thermal isolation may be provided in other ways, including for example a physical separation of the thermally coupled components from the other parts of the IC.

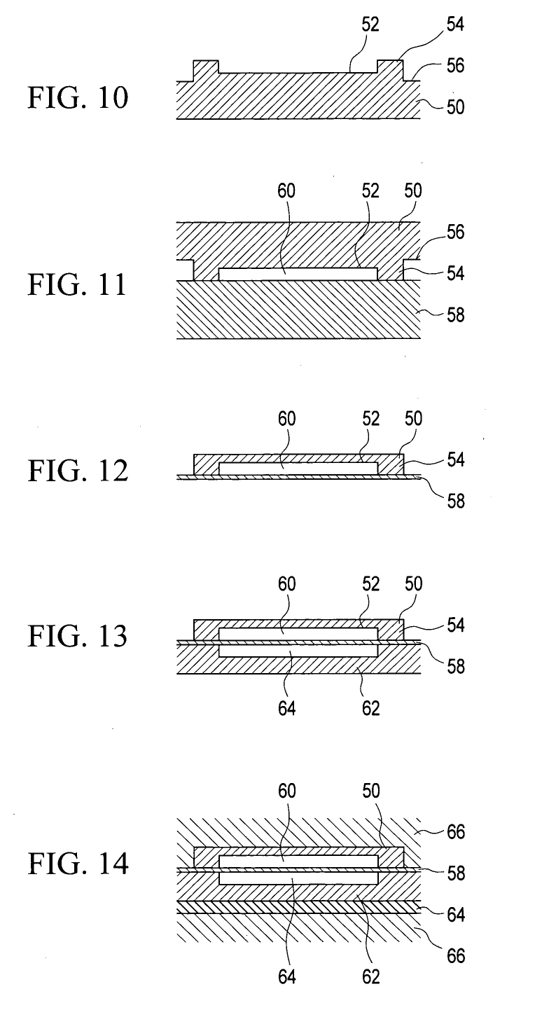

An example of a different thermal arrangement is described below with reference to FIGS. 10 to 14, which are sectional views illustrating steps in producing an IC in accordance with a further embodiment of the invention. This example makes use of fabrication techniques which are known for capping of micro electromechanical systems (MEMS) fabricated in silicon, but differs from such known techniques in providing a thermal cavity or isolated region which can be used in a similar manner to the thermally isolated bridge 14 as described above.

More particularly, a silicon wafer is etched in known manner to provide etched caps, for example square in plan view. FIG. 10 illustrates in cross-section one cap whose underside is etched in a wafer 50, the wafer having relatively shallow etched regions 52 within walls 54, these being square in plan view, and relatively deeper etched portions or singulation troughs 56 surrounding the walls 54.

As shown in FIG. 11, the etched wafer 50, inverted, is placed in intimate contact with a silicon wafer 58 to be capped, forming covalent bonds where the two wafers make contact and a cavity 60 between the wafer 58 and each shallow etched region 52 of the wafer 50. The circuits that are to be thermally isolated as described above are previously provided on the wafer 58 below the cavity 60.

The individual caps of the wafer 50 are separated by backside grinding of the wafer 50 to reach the singulation troughs 56. The wafer 58 is also ground to a minimal thickness, for example 0.1 mm., to minimize thermal conduction in the plane of the wafer. FIG. 12 illustrates the resulting capped and ground wafer.

In a similar manner, a backside cap 62 and cavity 64 are provided on the backside of the wafer 58 below the cavity 60, by etching another wafer in a similar manner to that shown in FIG. 10, placing it in intimate contact with the backside of the wafer 58, and optionally grinding its back side, so that the wafer 58 is capped on both sides as shown in FIG. 13. The backside cap 62 serves to restore physical robustness to the wafer by providing a more conventional die thickness to the assembled wafers. The capped wafer 58 is separated into individual ICs by dicing, a backside leadframe pad 66 and plastic encapsulant 68 being provided as shown in FIG. 14.

It will be appreciated that the silicon caps serve to thermally isolate the capped region of the wafer 58 from other parts of the wafer, in an alternative manner to that provided by the bridge 14 illustrated in FIGS. 1 to 6. The thickness of the wafer 58 is much greater than that of the bridge 14, so that thermal conduction in the plane of the wafer 58 is greater than in the case of the bridge 14, but the capped region is still relatively thermally isolated from other parts of the wafer 58 beyond the capped region. The silicon caps prevent the backside leadframe pad 64 and the plastic encapsulant 66 from contacting the capped region of the wafer 58, increasing the thermal impedance between the capped region of the wafer 58 and its surroundings. Fabrication of the assembled wafer of FIG. 14 may be more convenient than fabrication for the silicon bridge arrangement of FIGS. 1 to 6, because it avoids the need for etching of the bridge.

Although particular embodiments of the invention are described above in detail, it can be appreciated that numerous modifications, variations, and adaptations may be made without departing from the scope of the invention as defined in the claims.

1. An integrated circuit comprising a circuit component of the integrated circuit and a heating component thermally coupled together and relatively thermally isolated from other parts of the integrated circuit, and a control circuit for controlling the heating component for heating the circuit component to a temperature greater than a maximum operating temperature of said other parts of the integrated circuit.

2. An integrated circuit as claimed in claim 1 wherein the thermally coupled components are provided on a bridge over a cavity in the integrated circuit to provide the relative thermal isolation of the thermally coupled components from said other parts of the integrated circuit.

3. An integrated circuit as claimed in claim 2 wherein the control circuit is a part of the integrated circuit.

4. An integrated circuit as claimed in claim 1 wherein the thermally coupled components are provided in a region of the integrated circuit having a relatively thin substrate and caps over said region to provide the relative thermal isolation of the thermally coupled components from said other parts of the integrated circuit.

5. An integrated circuit as claimed in claim 4 wherein the control circuit is a part of the integrated circuit.

6. An integrated circuit as claimed in claim 1 and including a sensing component thermally coupled to the heating component, wherein the control circuit is responsive to the sensing component for controlling the heating component.

7. An integrated circuit as claimed in claim 6 wherein the thermally coupled components are provided on a bridge over a cavity in the integrated circuit to provide the relative thermal isolation of the thermally coupled components from said other parts of the integrated circuit.

8. An integrated circuit as claimed in claim 7 wherein the control circuit is a part of the integrated circuit.

9. An integrated circuit as claimed in claim 6 wherein the thermally coupled components are provided in a region of the integrated circuit having a relatively thin substrate and caps over said region to provide the relative thermal isolation of the thermally coupled components from said other parts of the integrated circuit.

10. An integrated circuit as claimed in claim 9 wherein the control circuit is a part of the integrated circuit.

11. An integrated circuit as claimed in claim 1 wherein the control circuit is responsive to a control voltage for controlling the heating component.

12. An integrated circuit as claimed in claim 1 wherein at least one of the thermally coupled components comprises a resistor.

13. A method of controlling a temperature-dependent characteristic of a circuit component of an integrated circuit, comprising the steps of:
thermally coupling the circuit component to a heating component and relatively thermally isolating the thermally coupled components from other parts of the integrated circuit; and
controlling the heating component to heat the thermally coupled components to a temperature greater than a maximum operating temperature of said other parts of the integrated circuit.

14. A method as claimed in claim 13 and including the step of maintaining a substantially constant temperature of the thermally coupled components thereby to maintain said temperature-dependent characteristic of the circuit component substantially constant.

15. A method as claimed in claim 14 wherein the circuit component comprises a resistor and the temperature-dependent characteristic comprises a resistance of the resistor.

16. A method as claimed in claim 13 and including the step of controlling temperature of the thermally coupled components thereby to adjust said temperature-dependent characteristic of the circuit component.

17. A method as claimed in claim 16 wherein the circuit component comprises a resistor and the temperature-dependent characteristic comprises a resistance of the resistor.

18. An integrated circuit comprising:
a substrate including a cavity in the substrate and a bridge over the cavity;
a circuit component of the integrated circuit on the bridge whereby it is relatively thermally isolated from other parts of the integrated circuit not on the bridge; and
a heating component on the bridge, the heating component and the circuit component being relatively thermally coupled together, whereby the circuit component can be heated by the heating component to a temperature greater than a temperature of said other parts of the integrated circuit.

19. An integrated circuit as claimed in claim 18 and including a sensing component on the bridge relatively thermally coupled to the heating component and the circuit component.

20. An integrated circuit as claimed in claim 18 and including a control circuit for controlling the heating component thereby to control a temperature to which the circuit component is heated.

21. An integrated circuit comprising:
a substrate having a region having caps providing relative thermal isolation of said region from other parts of the substrate;
a circuit component of the integrated circuit in said region whereby it is relatively thermally isolated from other parts of the integrated circuit not in said region; and
a heating component in said region, the heating component and the circuit component being relatively thermally coupled together, whereby the circuit component can be heated by the heating component to a temperature greater than a temperature of said other parts of the integrated circuit.

22. An integrated circuit as claimed in claim 21 and including a sensing component in said region relatively thermally coupled to the heating component and the circuit component.

23. An integrated circuit as claimed in claim 21 and including a control circuit for controlling the heating component thereby to control a temperature to which the circuit component is heated.

24. A method of making an integrated circuit having a substrate with a region having caps providing relative thermal isolation of said region from other parts of the substrate, comprising the steps of:
providing a heating component and a circuit component of the integrated circuit in said region of a first wafer;
etching an underside of a cap in a second wafer;
contacting the first and second wafers to provide the cap over said region;
backside grinding the first wafer to produce a relatively thin substrate in said region;
etching an underside of a second cap in a third wafer; and
contacting the first and third wafers to provide the second cap under said region.
